(19) United States
(12) Patent Application Publication
(10) Pub. No.: US 2023/0229951 A1
(43) Pub. Date: Jul. 20, 2023

(54) QUANTUM ANALOG COMPUTING AT ROOM TEMPERATURE USING CONVENTIONAL ELECTRONIC CIRCUITRY

(71) Applicant: Technologies infinityQ Inc., Dollard-des-Ormeaux (CA)

(72) Inventors: Jean-Michel SELLIER, Montreal (CA); Kristina KAPANOVA, Sofia (BG)

(21) Appl. No.: 17/927,990

(22) PCT Filed: May 28, 2021
(86) PCT No.: PCT/CA2021/050723

§ 371 Date: Nov. 28, 2022

Related U.S. Application Data
(60) Provisional application No. 63/032,426, filed on May 29, 2020.

(51) Int. Cl. G06N 10/40

(52) U.S. Cl. CPC G06N 10/40

(57) ABSTRACT

An integrated circuit and a method for operating the integrated circuit to perform quantum analog computing. The integrated circuit comprises a plurality of qubits connected to each other, each qubit of the plurality of qubits comprising resistors, inductors, capacitors and a switch, which can be implemented using CMOS elements, wherein the qubits are connected to each other according to a connectivity topology, such as a Hopfield network, that provides an analog of quantum behavior at room temperature.

### CROSS-REFERENCE TO RELATED APPLICATIONS

This application claims the priority or benefit of U.S. Provisional Pat. application 63/032,426, filed May 29, 2020, the specification of which is hereby incorporated herein by reference in its entirety.

### BACKGROUND

### (A) Field

The subject matter disclosed generally relates to quantum computing devices. More specifically, it relates to a quantum analog device comprising analog electronic devices working at room temperature to carry out computations by exploiting certain quantum effects.

### (B) Related Prior Art

### Quantum Computing

Quantum mechanics was successfully applied in a variety of domains to improve our understanding about polymers, semiconductors, superfluids, superconductors, among many others. In 1982, Richard Feynman pointed out that some quantum mechanical effects cannot be efficiently simulated on a classical von Neumann architecture [1]. This, in turn, led to the proposal that one can perform more efficient computations if quantum effects are harnessed, leading to quantum computers [2]. Works by Feynman [1], Manin [2], Pople [3], Kohn [4], Deutsch [5], and others, conveyed that to simulate quantum mechanics on von Neumann computers would necessitate exponential growth of hardware resources with the growth of the problem size, making certain problems incapable of simulation. Those difficulties could be possibly circumvented by a quantum computer. In a very general sense, with quantum computing, one tries to solve problems by exploiting quantum effects to inspect computational correlation and then reach a correct answer through effective interference.

Several quantum computing paradigms have been introduced which come with different advantages and disadvantages. The most widely known one is the gate paradigm which is analogous to the binary logic gates in classical computers. Quantum information is processed by means of quantum gates, implementing complex circuits to achieve practical functionalities with the promise of incredible advantages over classical computing. But gates are not the only way to realize quantum computing. In adiabatic quantum computing [23], the computation starts from an initial Hamiltonian with an easy-to-construct ground state. The Hamiltonian is then gradually varied into a final Hamiltonian, whose ground state encodes the solution to the computational problem. The adiabatic model is pursued on the theory that the architecture may have a certain inherent fault tolerance [24,25,26] due to resistance to slowly varying control error. Moreover, the energy gap may provide inherent resistance to noise, due to stray couplings to the environment, for example, if noiseless qubits are developed [25]. It has been theoretically shown that adiabatic quantum computing is as powerful as the circuit-based approach, but it brings with it a significant cost in terms of additional physical qubits (just like in the gate paradigm).

The architectures described above can be realized with various physical objects acting as qubits [36]. Examples include trapped ions [37], quantum dots, cavity QED [38], neutral atoms, superconducting electrical circuits wherein many electrons are moving [39], and liquid and solid state nuclear magnetic resonance [40], among others.

The realization of practical quantum computing is dependent on the development of better (noiseless) qubits, better interconnects, improved control, and error correction. For its part, error correction is governed by the threshold theorem which involves three main assumptions: 1) errors occur independently (on qubits, gates and measurements), with no spatial or temporal correlations; 2) one can perform many gates simultaneously on physical qubits; and 3) the noise is brought under a certain threshold with quantum error correction algorithms such that even when more qubits are added, one can eliminate error faster than it is created, clearing the road for the quantum computer to emulate a perfect quantum system. As a result, one can perform accurate computations with hundreds of digits after the decimal. Since it will be capable of dealing with such numbers efficiently (something digital computers, above a certain digit, cannot), a quantum computer can in theory solve problems computationally intractable with digital computers. At the current moment, no such fault-tolerant quantum computation has been achieved.

### SUMMARY

According to a first aspect, there is provided quantum analog computing device, or an integrated circuit for quantum analog computing, the integrated circuit comprising:
a plurality of qubits connected to each other, each qubit of the plurality of qubits comprising resistors, inductors, capacitors and a switch, wherein the qubits are connected to each other according to a connectivity topology that provides an analog of quantum behavior at room temperature.

According to an embodiment, the connectivity topology is a Hopfield network.

According to an embodiment, each qubit in the Hopfield network is connected to all other qubits of the Hopfield network.

According to an embodiment, the qubits are connected to each other using at least one of: an inductor and a capacitor.

According to an embodiment, each qubit comprises a metal oxide semiconductor (CMOS).

According to an embodiment, the qubits are operating at a room temperature.

According to an embodiment, the qubits are operating at a temperature of between 0 and 30 degrees Celsius.

According to an embodiment, each qubit of the plurality of qubits comprises:
a first resistor, a voltage source, a first inductor, a first capacitor, and a shunt capacitor connected in a first series circuit, the shunt capacitor having a first node on one side and a second node on another side; and
the switch, a second resistor, a second inductor, and a second capacitor connected in series and forming a second series, the second series being connected in parallel to the shunt capacitor at the first node and the second node.

According to an embodiment, the voltage source is controlled to set each qubit with a particular initial state.

According to an embodiment, the integrated circuit is operable to reach a stable state, the integrated circuit measuring a voltage on each qubit to determine the voltage of each qubit associated to a current state in order to perform computation.

According to another aspect, there is provided a method comprising the steps of:
providing and connecting a plurality of qubits connected to each other according to a connectivity topology which is an all-to-all topology, each qubit of the plurality of qubits comprising resistors, inductors, capacitors and a switch to be equivalent to an atomic qubit;
setting an initial voltage of each qubit of the plurality of qubits; and
operating the plurality of qubits at the room temperature to reach a final state representative of a solution to a given problem and measuring an associated voltage of each one of the plurality of qubits to perform quantum analog computation to determine the solution.

According to an embodiment, there is further provided a step of operating amplifiers used to connect the qubits by the connectivity topology.

According to an embodiment, connecting the plurality of qubits according to the connectivity topology comprises connecting the plurality of qubits according to a Hopfield network built with resistors and capacitors.

According to an embodiment, each qubit in the Hopfield network is connected to all other qubits of the Hopfield network.

According to an embodiment, providing and connecting a plurality of qubits comprises connecting each qubit to all other qubits of the plurality of qubits using at least one of: an inductor and a capacitor.

According to an embodiment, each qubit comprises a metal oxide semiconductor (CMOS).

According to an embodiment, the qubits are operated at a temperature between 0 and 30 degrees Celsius.

According to an embodiment, each qubit is connected to a plurality of other qubits and all qubits participate in calculation, such that no qubit is used for error correction.

### BRIEF DESCRIPTION OF THE DRAWINGS

Further features and advantages of the present disclosure will become apparent from the following detailed description, taken in combination with the appended drawings, in which:

FIG. 1 is a schematic diagram illustrating a circuit used to provide a classical circuit analog to electromagnetically induced transparency (EIT), according to an embodiment of the invention;

FIG. 2 is a schematic diagram illustrating a coupled RLC circuit used to model a 4-level atomic system, where R_{1,2,3}, C_{1,2,3}, L_{1,2,3} and V_{s1,s2} are resistors, capacitors, inductors and alternating voltage sources, respectively, and capacitor C is shared between loops 1-3 and 2-3, according to an embodiment of the invention;

FIG. 3 is a schematic diagram illustrating a network of qubits (in green, left half of the network graph) which are fully connected between themselves and the ancilla (in red, right half of the network graph) connected to every qubit through coupling (gates), according to an embodiment of the invention;

FIG. 4 is a schematic diagram illustrating an electric circuit corresponding to equation 10 (described further below), with fast amplifiers, according to an embodiment of the invention;

FIG. 5 is a schematic diagram illustrating an electric circuit modeling a neural circuit with electrical components, where the neuron outputs can be connected to the input of any neuron (the black squares in this case represent resistive connections between the outputs and inputs; the circles in the amplifiers represent connections from inhibitory connections), according to an embodiment of the invention;

FIG. 6 is a schematic diagram illustrating an electric circuit embodying a 4-bit analog-to-digital converter (ADC) computational network, where the input is analog, while the digital representation of the input is V₃, V_{2,} V_{1,} V₀ and is carried out as a binary value from the output amplifier voltage, according to an embodiment of the invention;

FIG. 7 is a schematic diagram illustrating the Chimera graph created by D-Wave comprising an NxN grid of unit cells with eight qubits per cell, fully interconnected within the cell, and longitudinally coupled to four other qubits, according to the prior art;

FIG. 8 is a schematic diagram illustrating the Q5 coupling map, by IBM, according to the prior art;

FIG. 9 is a schematic diagram illustrating an electronic semiconductor-based qubit, or “CMOS Qubit”, comprising a combination of resistors, capacitors, inductors and a switch, according to an embodiment of the invention;

FIG. 10 is a schematic diagram illustrating CMOS Qubits connected together in a connectivity topology according to a network which, at run time, performs quantum analog computing, according to an embodiment of the invention;

FIG. 11 is a flowchart illustrating a method for operating an electronic semiconductor-based qubit, or “CMOS qubit”, comprising a combination of resistors, capacitors, inductors and a switch, to perform quantum analog computing, according to an embodiment of the invention;

FIG. 12 is a flowchart illustrating a method for operating an electronic semiconductor-based qubit, or “CMOS qubit”, connected according to a connectivity topology, according to an embodiment of the invention;

FIGS. 13A-13B are graphs illustrating a comparison of simulated and experimental results of Rabi oscillations observed during the simulation or experiment for different values of the circuit representing the pump laser, and the Fourier transform thereof, according to an embodiment of the invention;

FIG. 13C is a diagram illustrating an atomic system undergoing laser pumping and to which the analog circuit operated to arrive at the results of FIGS. 13A-13B is an analog;

FIGS. 14A-14B are graphs illustrating a comparison of the time to perform the traveling salesperson problem with a growing number of “cities”, between a device operated according to an embodiment of the invention and a benchmark using Gradient Descent on a “normal” computer;

FIG. 15 is a graph illustrating a comparison of the time to solve the Black-Sholes model with a growing number of price points, between a device operated according to an embodiment of the invention and a benchmark using a classical stochastic optimization method on a “normal” computer; and

FIG. 16 is a set of graphs illustrating, in relation with the example of FIG. 15, the accuracy of the quantum analog results compared to CMAES results and implicit method for the Black Scholes model for 10 (upper left plot), 50 (upper right plot), 100 (lower left plot), and 200 (lower right plot) price points.

It will be noted that throughout the appended drawings, like features are identified by like reference numerals.

### DETAILED DESCRIPTION

### Analog Computation

Analog computation refers to an analogy — or a systematic relationship — between the physical processes in the computing device and those in the system it is modeling/describing. An analog computer is therefore an analog of the particular system it is set to describe [34], [35]. For instance, electrical quantities such as voltage, current, conductance can be used as analogs for fluid pressure, flow rate, and pipe diameter of a hydraulic system. Stated differently, the physical quantities of the analog device follow the same mathematical laws as the physical quantities in the system under study. While the dynamics of an analog computer typically perfectly matches the dynamics of the original system [36], it is also true that different devices or systems can be analogs of one another without necessarily having any physical resemblance [34].

In analog computers, rather than operating through the manipulations of numbers as digital computer do, numbers emerge as a result of measurements of physical parameters. Analog computers use continuously adjustable quantities of the system in order to codify a given problem. The time evolution of the voltage waveform of the analog computer represents the encoding of the solution of a given problem. Electronic components (physical devices) are used to sum, multiply, and integrate physical quantities like these signals. These components are connected in a way that the voltages of the analog computer are related by the same mathematical equations as the original physical variables. Some of the basic components of an analog system are amplifiers, potentiometers, multipliers and function generators through which one can carry out mathematically operations such as addition, subtraction, multiplication, division, integration, and so on. One of the advantages of analog systems is the ability to connect these components in a variety of ways, depending on the physical system under consideration. A key technological development leading to the wider adoption of analog computations was the alternating and direct current operational amplifier, which can perform mathematical operations such as addition, subtraction, integration and differentiation electronically.

Two main considerations were used for evaluating the computation on analog computers: accuracy and precision. Accuracy pertains to the relationship between the simulation and the primary system being simulated, or put another way - the relationship between the computational result and the mathematical correct results. Precision is, on the other hand, a stricter notion, referring to the quality of the computing device and is typically dependent on the resolution (quality of operation) and stability (lack of drift). Therefore, by a precision of 0.01% one understands that the results will be bound within 0.01% of the represented value for a reasonably long period of time. In order to compare analog devices, one usually expresses precision as the difference between the maximum and minimum representable values. Multiple factors affect accuracy and precision. These factors include the choice of physical process, the set-up of the machine, as well as the physical effects (loading, leaking and other losses) - the quality of the resistors or capacitors and other components used to construct the machines. Noise affects the system as well, and it can be intrinsic (e.g. thermal noise) as well as extrinsic (e.g., ambient radiation). There are several advantages of analog computers, including speed, inherent natural parallelism, and small size. These advantages stem from the fact that analog computations are close to the physical processes that realize them. In principle, any mathematically described physical process can be used for analog computation.

Analog computers have a long history prior to the digital age, and have been applied to an extensive variety of fields. While, for the last 50 years, digital computing has been the dominant paradigm, with the slowing down of Moore’s law, several non-Von Neumann hardware architectures have emerged such as: analog memory [37], neuromorphic photonics [38],[39], optical co-processors [40], as well as quantum computing to tackle complex tasks more efficiently than digital processors.

An interesting perspective on the field of quantum computing was raised by D. Ferry in 2001 where the role of the use of parallel analog computation for speed gain was discussed. Ferry examines a qubit as a analog quantity, showing that in certain processes the real speed up comes from the analog quantities and advantages and “not from the use of quantum mechanics”. Kish, taking inspiration from the same paper, has pro-posed a quantum computing approach via Hilbert space computing with analog circuits [42], an approach he calls a Hilbert-space-analog (HSA) computer.

Analog computer has been defined as devices used to solve a mathematical problem with respect to a primary physical system. This is due to the same, or related mathematical structures for both the computational and primary (physical) systems. Even though, from a practical standpoint, certain analog systems are better suited than others, in principle any physical system can be used as long as it obeys the same equations as the primary system. As such the analog device can be used to demonstrate quite clearly multiple facets of the mathematics of quantum mechanics since an analog device computes by exploiting physical phenomena directly. This idea was also supported by Feynman, who showed one can reduce an exponentially complex problem of calculated probabilities to one of polynomial complexity of simulated probabilities. Therefore, in the case of NP complete problems one can create such a physical system, which mathematical description corresponds to those of the specific NP problem. Thereupon, such a physical system can be realized through appropriate analog device, which is able to simulate the corresponding NP-complete problem. The reason for the growing attraction of quantum computing comes from its analog nature, which is based on physical simulations of quantum probabilities.

Taking into account the nature of computation, as well as the analogy between physical systems, realized in terms of analog computational devices, a new way to perform computation is proposed herein, called quantum analog computing. It is analog in two ways. First, it relies on analogies with quantum systems (i.e., the computing arrangement has the same behavior as the “real” system being modeled, as described above). Second, it employs analog electronics. In practical terms, this means that instead of dealing with actual atoms or molecules to carry out quantum computations (which are extremely sensitive), analog circuits based on basic electronic elements (for example CMOS-based) can be used to achieve some quantum computing capabilities.

There is described below a method for performing quantum analog computing (including, without limitation, tasks such as quantum annealing) with conventional electronics. Each conventional electronic computational structure (qubit) having the following basic elements: resistors, capacitors, inductors and a switch or their equivalent is capable of working at room temperature and is now referred to hereinafter as a “CMOS Qubit”. The commercial term “Qsistor” may be used as a trademark. These CMOS Qubits are connected together in a particular way (a connectivity topology) described further below. More specially, this can be a CMOS chip composed of qubits designed and controlled through conventional electronic circuitry.

The analog circuits (qubits), connected by an all-to-all connectivity, allow the problem to be codified into the topology of the device. The computation proceeds until a stationary regime is reached. The stationary regime represents the solution of the problem. According to an embodiment, and as detailed further below, the qubits can be connected according to a Hopfield network to perform such a task.

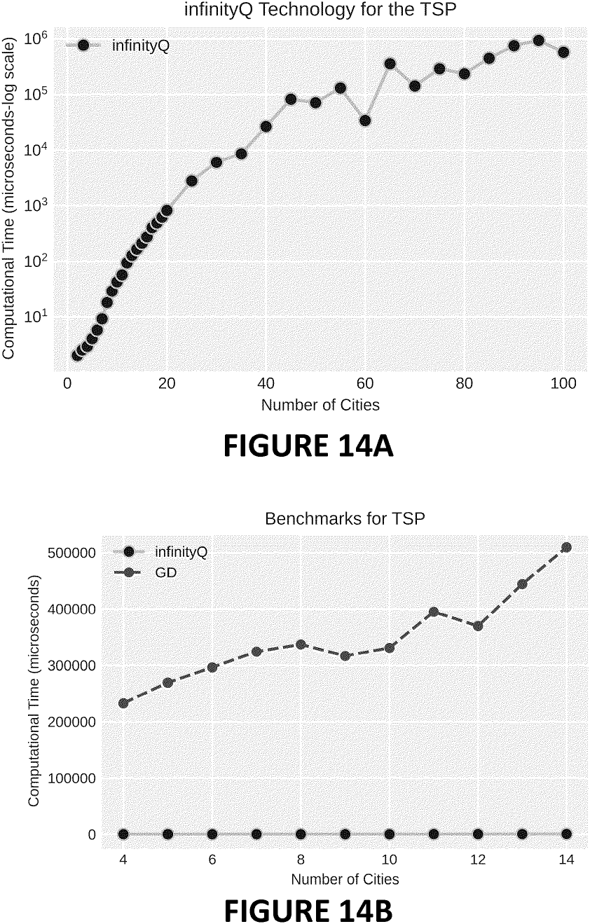

For example, FIG. 14 is a schematic diagram illustrating qubits, such as CMOS qubits, connected together in a connectivity topology according to a network which, at run time, performs quantum analog computing, according to an embodiment of the invention. Each qubit on one side is connected to each qubit in the other side, although this is a non-limiting representation. Other representations would be possible, such as a circle. According to an embodiment, the topology of connections implements the all-to-all connectivity by which all qubits participate in calculations.

As they use conventional electronics, connected CMOS qubits are operable at room temperature, as an integrated circuit device. According to an embodiment, the room temperature which is the temperature of the environment in which the computer is operated is typically between -10° C. and 40° C., more specifically between -5° C. and 35° C., more specifically between 0° C. and 30° C., more specifically between 15° C. and 25° C.

Moreover, due to the system’s individual components as well as the connectivity type, the system does not require any error correction and all available qubits participate in the computational process. Also, since the system is built from traditional CMOS type equipment, the architecture allows significant scalability, allowing thousands of qubits in the system than what is currently possible in the industry nowadays, where this number is still limited due to many practical considerations such as the need for cryogenic technology, which is not required in the system described herein below.

Since there is no need for cryogenic technology and since all available qubits participate in the computational process (i.e., none is needed for error correction), the circuitry and its environment are made much simpler than currently available technology, with the advantage of permitting rapid changes in circuitry. Changes in circuitry need to be made to perform different computing tasks. Making these circuitry changes rapidly is an advantageous result of using the system described herein to perform quantum analog computing.

There are now described the foundational aspects on which the quantum analog computing device according to the invention is built, such as the qubit, followed by a description of carrying out certain quantum effects through classical electronic circuitry according to the invention.

### Foundational Aspects

### 1. Qubit - Definition

In this section, there is provided a general description of the basic computational structure (qubit). In classical information processing, operations are performed using bits. Those are two-state systems, with the states being 0 and 1. By grouping those binary bits together we can represent information, while the manipulation of those bits allows classical computers to carry out arbitrary computations. Respectively a bit can be represented as a switch which is either on or off. Correspondingly, in a quantum system the fundamental element in quantum information is the quantum bit, also known as qubit. A qubit is a unit vector of a two-dimensional vector space which represents particular basis states (two or more discrete energy states) such as |0〉 or |1〉.

In a contrast to a classical bit which can have two states, 0 and 1, a qubit can be in a superposition state ψ = cos(θ/2)|0〉 + e^{iϕ}sin(θ/2)|1〉, which corresponds to the classical version of the bit states. In a quantum computer, qubits represent the encoding of information, and those qubits require strong interaction with one another. Compared to classical information system, qubits are not confined to two states and instead can be found in arbitrary superposition states. When exploiting the superposition states to carry out information processing, where a state can be described as

$$\left(Ψ\right〉 = α \left|0\right〉 + β \left|1\right〉$$

with α and β being complex numbers, qubits become more powerful than their classical equivalent (bit).

Another key property is entanglement, where qubits interact with one another in a way that following that interaction, they cease to be independent. For instance, the Bell state, describing entanglement such as

$$\left|Ψ\right〉 = \frac{1}{\sqrt{2}} \left(\left|00\right〉 + \left|11\right〉\right)$$

There is zero probability of observing |01〉 or |10〉, while the probability of |00〉 and |11〉 are each ½. Due to entanglement the probabilities of multi-qubit states cannot be separated into product of individual probabilities. Importantly entanglement can be achieved between physically separated particles, and it can be preserved in time and through transformations and measurements.

The completion of a quantum computation through qubits, requires the measurement (read out) of the state of the qubit. When this state of a qubit is measured, the quantum nature of the qubit is momentarily lost, meaning the superposition of the basis states breaks down to either |0〉 or |1〉., thus becoming similar to a classical bit. This naturally leads to the tradeoff between control and coupling in order to preserve quantum coherence.

While the power of classical information processing stems from the manipulation of a groups of bits (depending on the particular paradigm), in quantum computation the advantages become evident in a system with two or more qubits. Those qubits can be physically realized in different ways - e.g., a single photon (particle of light), a single atom or a single electron, etc. Multiqubit operations have been introduced from different implementations such as superconducting qubits [7, 8, 9], trapped-ion [10, 11, 12], solid-state spin [13, 14], nuclear spin [15], neutral atom [16, 17]. The coherence times in those systems are varied and often represent a serious limitation for those architectures.

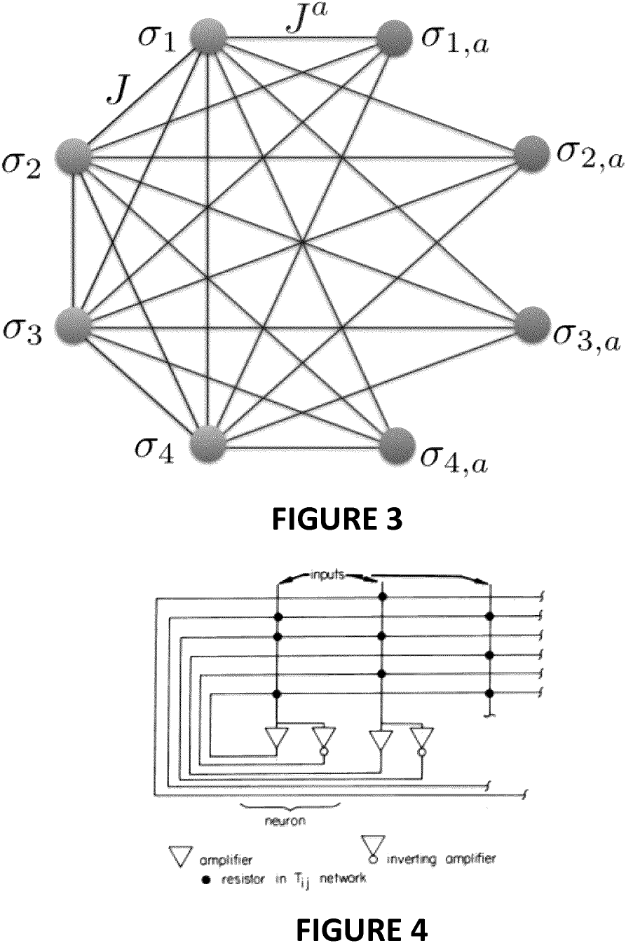

Peter Shor was the first to propose a quantum error correction mechanism, where quantum information is redundantly encoded by its entanglement within a larger system of qubits [21], providing error correction during quantum computation. Therein, as previously mentioned two types of qubits are necessary - physical qubits performing computation and extra qubits, known as ancillas, which are utilized to detect errors before they accumulate. Therefore, multiple physical qubits are to be connected in a large network in order to operate a single logical qubit [22], that perform the computation at hand. This is an extremely important barrier in the capability of constructing a large-scale quantum machine. As shown in FIG. 3, for N qubits there would be N2 ancilla, necessitating N - 1 and 2N - 3 couplers (gates).

Compared to prior art quantum computing devices that need specific hardware and software error correction functionality, the quantum analog computing device according to an embodiment as described herein does not require any type of error correction functionality, since the device does not suffer from errors accumulating over time due to noise. The quantum analog computing device as described herein does not require additional qubits to serve as an error correction and, as a result, all available qubits, which can be in an all-to-all connectivity, participate in the computational process.

### 2. Analogy Between Quantum Two-State Systems and Specific Classical Systems

Although today we consider the Schrödinger equation as the standard quantum mechanical formalism, it is worth noting that it was developed on the basis of classical optical ideas [41].

In fact, throughout the history of science, researchers have relied on analogies to provide insights into unfamiliar concepts, systems, objects or events by considering the properties of an already known counterpart. In the case of quantum-classical wave analogies, two effects - one in a quantum system and another in a classical wave, represent different manifestation of the same underlying physical principles (the wavefunction of a photon corresponds to the classical electromagnetic field) [42], [43]. Much as in the early days of quantum mechanics scientists relied on those analogies to convey their knowledge of electromagnetism to the emerging theory, today, quantum-wave analogies are often used to provide an intuition in the investigation of new phenomena in classical waves.

There are a multitude of classical-classical, quantum-quantum, and quantum-classical analogies which are well known and accepted by the physics community for decades. In the current section, we are going to focus on the quantum-classical analogies specifically. Many classical-classical analogies exist. For instance: mechanics and electricity [44], inertial and electromagnetic forces [45], or mechanical system corresponding to phase transitions in a one dimensional medium [46]. Similarly there are many quantum-quantum analogies. Some quantum systems have classical analogs only in phase space, in other cases quantum states described by the Schrödinger equation are propagating through specific structures in the exact same way as electromagnetic fields propagate through optical structures. Another example is the quantum states defined by a Dirac-like equation that have analogs to optical fields propagating through special materials (e.g., graphene [47]).

One of the most incontrovertible evidence is the analogy between electron waves in a quantum waveguide and electromagnetic waves, allowing a variety of microwave device concepts to be used in developing quantum devices [48]. Several structures, based on such analogy have been already utilized, such as stub-tuning device [49], [50], cavity coupled to two quantum waveguides [51], and double-bend quantum waveguide [52]. An interesting case of electromagnetic waves and quantum wave functions analogy is the electron interference in solid-state devices. Devices include Fabry-Perot interference filters for electrons [53], narrow band pass interference filters [54], Butterworth equal-ripple impedance transformers for electron wave functions [55] and many others. The interested reader is invited to consult the review of quantum-like features by classical systems in [56]. Fano interference in quantum systems has been of increasing interest due to the potential of utilizing quantum systems of electron waveguide with an attractive potential.

For example, electromagnetically induced transparency (EIT) is a quantum interference effect occurring between two atomic states of a medium. It necessitates two indistinguishable quantum paths, which lead to the same final state. By applying electromagnetic field in EIT, one can significantly adjust the optical properties of a medium near atomic resonance. In such a near resonant field, the atoms are excited into higher energy states because they absorb energy from the surrounding field. This absorption spectrum follows a Lorentzian curve which is highest near the natural frequency of the atomic resonance transition. Therefore, in EIT, there are fields where each field has a distinct atomic transition. In a quantum mechanical system when many excitation paths are present, there would be interference among their probability amplitudes. As such one can consider EIT as an interference between transition paths. In quantum mechanics, the probability amplitudes (which can be positive as well as negative in their sign) have to be summed (and not the probabilities) and squared to acquire the complete transition probability between relevant quantum states [19]. Thus, interference between the amplitudes can lead to constructive interference (enhancing) or a destructive interference (complete elimination) in the total transition probability. One can interpret EIT as interfering paths among atomic states, while coherence would be the amount of interference.

Despite the fact that electromagnetically induced transparency is intrinsically a quantum mechanical effect, it can in fact be modelled as a classical system, where atoms are represented as oscillators to provide quantum computing. Coherence in this case can be associated with oscillating electric dipoles, propelled by coupling fields, which are influenced by coupling fields between pairs of quantum states in the system (i.e., |i〉 and |j〉). A very strong excitation occurs when an electromagnetic field is applied close to resonance when the electric dipole moves between two states. The presence of several paths to excite the oscillations at a certain frequency (wᵢⱼ) allows the emergence of interference. The contributions are summed in order to provide the total amplitude to the electric oscillation.

One example of quantum and classical phenomena described by similar mathematical models was provided in [19] where they model an atom as a harmonic oscillator, which is described by a particle with mass m₁, being subject to a harmonic force Fₛ = Fe^{-i(wst+ϕs)} and with resonance frequency w₁. The particle is attached to spring constants k₁and K, which are connected to a wall and a second particle with mass m₂ in a fixed position respectively. The EIT system is composed of a two-level (λ) system that is coupled to a shared level where k₁ = k₂ = k and m₁ = m₂ = m, and with the masses connected by springs representing the two-level atom. The pump field in EIT is achieved by coupling both oscillators to spring of constant K. The respective motion of the masses can be written such that x₁ and x₂ are displacements from the equilibrium positions defined as:

$${\ddot{x}}_{1} \left(t\right) + {γ}_{1} {x}_{1} \left(t\right) + {ω}^{2} {x}_{1} \left(t\right) - {Ω}_{r}^{2} {x}_{2} \left(t\right) = \frac{F}{m} {e}^{- i {ω}_{s} t}$$

and

$${\ddot{x}}_{2} \left(t\right) + {γ}_{2} {x}_{2} \left(t\right) + {ω}^{2} {x}_{2} \left(t\right) - {Ω}_{r}^{2} {x}_{1} \left(t\right) = 0$$

where

$${Ω}_{r}^{s} = K / m , {γ}_{1}$$

is the rate of energy dissipation on the first particle, and γ₂ is the rate of energy dissipation of the pumping transition.

An RLC circuit (composed of two RLC circuits coupled by a shunt capacitor) was used to study EIT by analyzing the absorption of electric power in resistances. The circuit is composed of an inductor L₁, capacitors C₁ and C thereby simulating the pumping oscillator (i.e., the quantum oscillator), while the R₁ resistor models the oscillator losses. The quantum system is constructed as a circuit with inductor L₂, and capacitors C₂ and C, while resistor R₂ acts to dampen the excited level. The shared capacitor C between the two RLC circuits acts as the coupling factor between the quantum system and pumping field and is responsible for controlling the pumping transition. Setting in the RLC circuit L₁ = L₂ = L which corresponds to m₁ = m₂ = m and rewriting equations (3) and (4) for the two charges q₁(t) and q2(t) we get:

$${\ddot{q}}_{1} \left(t\right) + {γ}_{1} {q}_{1} \left(t\right) + {ω}^{2} {q}_{1} \left(t\right) - {Ω}_{r}^{2} {q}_{2} \left(t\right) = 0$$

$${\ddot{q}}_{2} \left(t\right) + {γ}_{2} {q}_{2} \left(t\right) + {ω}^{2} {q}_{2} \left(t\right) - {Ω}_{r}^{2} {q}_{1} \left(t\right) = \frac{{V}_{S} \left(t\right)}{{L}_{2}}$$

where yᵢ = Rᵢ/Lᵢ, i = {1,2}, ω = 1/(LᵢCₑ₁), with

$${C}_{e 1} = \frac{C {C}_{2}}{C + {C}_{2}} , {Ω}_{r}^{2} = 1 / \left({L}_{2} C\right)$$

and ω₁ = ω₂.

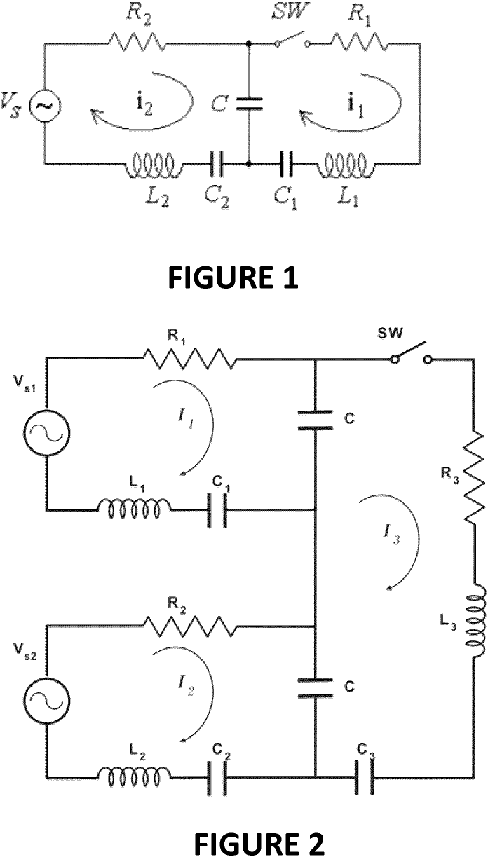

Importantly, equations 5 and 6, describing a coupled system, are in fact equivalent to the Schrödinger’s equation of a two-state system. Thus, it is shown that the RLC circuit and the two-level system (λ) both evince resonance effects - meaning the transferred energy in the system is dependent on the frequency of the drive. The interference occurs when voltage is applied to the RLC circuit, while the transferred power is provided by the right-hand loop in the RLC circuit, as shown in FIG. 1, which shows the circuit used to illustrate how the classical analog circuit compares to EIT. Those two parts of the system attempt to drive the system respectively and finalize by canceling out at zero detuning.

The ability to model mathematically EIT effects through an RLC-type circuit enables us to model qubits as CMOS devices, by utilizing classical electronic structures and to achieve computationally useful quantum effects if connected properly (see for instance FIG. 2 which shows how a coupled electric circuit is devised to model tripod 4-level atomic system).

The work of Alzar et al [19] depicted a coupled RLC system representing a two-state quantum system. Consequently, a qubit can be modeled as a coupled RLC circuit in a similar manner as the one depicted in FIG. 1 which is of great relevance in the present context.

To generalize, circuits comprised of resistors, capacitors, inductors and a switch or their equivalent can be coupled together to reproduce two-state, three-state, four-state, ..., N-state atomic systems and, accordingly, these circuits can be coupled to form a qubit.

These systems comprised of resistors, capacitors, inductors and a switch or their equivalent can be implemented using currently available technology arranged in a novel way to form such coupled systems, forming a qubit. The qubit can therefore be built on an integrated circuit using standard fabrication technology, such as a CMOS chip using existing lithography methods, to perform quantum computing.

### 3. Exploring the Suitability of Collective Computing

Physical reservoir computing has been implemented in electronic circuits, including coupled nonlinear oscillators and coupled phase oscillators. Within the field of quantum computing, the reservoir has been represented as a quantum many-body system such as interacting qubits or fermions that are driven by Hamiltonian dynamics. A different approach to implement quantum reservoir computing is with a continuous-variable system, where the reservoir represents a single nonlinear oscillator. Sarpeshkar (2014) has shown that collective analog computing is one of the most efficient and scalable computational approaches. In such a case, many moderate-precision analog devices interact to preserve information. We note that this is similar to the biological neurons.

### 3.1. Hopfield Network

In 1982, John Hopfield introduced a class of artificial neural networks which functions to store and retrieve memory like the human brain (although this is not the only possible use for such networks). The network consists of fully connected discrete neurons, having two states - either on (+1) or off (-1). The state of the neuron will be renewed depending on the input it receives from other neurons [24]. The initial purpose of a Hopfield network was the ability to store a number of patterns or memories, i.e., content-addressable memories. The network is capable of recognizing any of the learned patterns by being exposed to only partial or corrupted information about the pattern, allowing it eventually to settle down and to provide as an output the closest pattern available.

The Hopfield network is a single layer, fully interconnected network, i.e., each of the neurons is interacting with all others, where given two neurons i and j there is a connectivity weight wᵢⱼ between them which is symmetric, wherein wᵢⱼ = wⱼᵢ with zero self-connectivity wᵢᵢ = 0. Assuming there are N neurons in a network with values xᵢ = ±1, then the update rule for node i is provided by the following statement: if hᵢ ≥ 0 then 1 ← xᵢ otherwise -1 ← xᵢ where

$${h}_{i} = {\sum }_{j = 1}^{N} {w}_{i j} {x}_{j}$$

There are two ways to update the processing nodes. The first is by a synchronous update where, at each time increment, all units are updated simultaneously. The second update rule is asynchronous - at each point of time a unit is selected at random (or according to some rule) and its new state is computed. Individual units preserve their own states until they are selected for an update. Asynchronous update ensures that the next state is at most a unit Hamming distance from the current state.

Similarly to other artificial neural networks, a Hopfield network also has a cost function associated with it. The difference is that while traditional cost functions in artificial neural networks are a function of the weights of the network, in the Hopfield case, it is a function of the states of the network. Typically, a cost function for neural networks assesses the error between the network’s output given a training sample and the desired output of that sample. The goal is to minimize the function by using some training algorithm. In the case of a Hopfield network, there is no labeled training set. The network takes patterns and memorizes them. As such, Hopfield mathematically characterized the effects of the effect of changes of individual neurons on the energy property of the entire network. Hence, Hopfield links the individual local interactions between neurons with the global behavior of the system.

All processing units are initialized in a state and are then evolved toward a local energy minimum. Supposing the state of the network at time t is x(t) ∈ 0, 1ⁿ, we can update the state according to

$${x}_{i} \left(t + 1\right) = \left\{\begin{matrix}1 & i f {\sum }_{j} {w}_{i j} {x}_{j} > 0 \\ - 1 & o t h e r w i s e\end{matrix}\right)$$

with the energy being

$$E \left(x \left(t\right)\right) = \frac{- 1}{2} {\sum }_{i} {\sum }_{j} {w}_{i j} {x}_{i} \left(t\right) {x}_{j} \left(t\right)$$

with wᵢⱼ being the weight between i and j, with wᵢⱼ = wⱼᵢ and wᵢᵢ = 0 for all i.

A corollary of the energy function is the proof of the convergence theorem, according to which in an asynchronous updating of neurons, a stable state will be reached in a finite number of steps. If the neuron update is performed in a cyclical, random but fixed manner, only N2^{N} steps (individual neurons updates) are required, with N being the number of neurons in the Hopfield network.

When a final stable state is reached (i.e., an equilibrium state), the correct pattern is recalled by the network. In the case of symmetric weights, the network always reaches a stable point. A corollary is that the energy of the system cannot be increased since it may then lead to instability. Consequently, in a Hopfield model with symmetric weights, the network can move to lower or same energy state. To mitigate the error in pattern recall due to false minima, one can either utilize a stochastic update for states or store desired patterns at lowest energy minima. Further reduction of the error in pattern recall can be achieved by using suitable activation dynamics.

The Hopfield network provides a path for content-addressable memory (associative memory) — the ability to store information in the stable states of a dynamical system — implementation in hardware. Hopfield achieved this through utilization of simple electronic components. There can be a graded response neuron, which has continuous input-output relations and integrative time delays due to capacitance [25] so that

$${V}_{j} = {g}_{i} \left({u}_{i}\right)$$

with g bounded below and above the monotone sigmoid increasing function gᵢ(uᵢ) = 1/(1 + exp (uᵢ)). Vᵢ represents the short-term average of the firing rate of neuron i, and the output of the neuron will be represented by Equation (10) (see FIG. 4). The rate of change is described by the resistance-capacitance charging equation:

$${C}_{i} \left(\frac{d {u}_{i}}{d t}\right) = {\sum }_{j} {T}_{i j} {V}_{j} - \frac{{u}_{i}}{{R}_{i}} + {I}_{i}$$

where C is input capacitance, R is the transmembrane resistance, while TᵢⱼVⱼ represents the electrical current input, and

$${u}_{i} = {g}_{i}^{- 1} \left({V}_{i}\right)$$

. Importantly, the resistance Rᵢ is dependent on the connection matrix:

$$\frac{1}{{R}_{i}} = {\sum }_{j} \left|{W}_{i j}\right| + \frac{1}{{r}_{i}}$$

with rᵢ being the input resistance needed to model cell membrane impedance. In other words, the strength of each synapse is represented by the conductance value at each unit.

The dynamics of the energy function of Hopfield networks is a Lyapunov function, which provides knowledge of the possible final states. The Lyapunov function decreases in a monotone manner under the dynamics, being bounded below. When the T is symmetric, the dynamics of the system has a Lyapunov function, in which case the monotone gain function g (which converts the potential into the neuron’s firing rate) is inverted to g⁻¹. Importantly, in a severe limiting case where T has no diagonal elements, the input/output function becomes step-wise from zero, and is scaled to 1. In this case the energy minima E is located at the corners of the hypercube. Importantly, here the stable states of the graded response neurons become the exact same as the stable states in the binary version. To find the minimum in the energy map, one can scale the steepness of the function by a factor λ without removing the output asymptote. Should there be a network with asymmetric connections, then basins of attraction may correspond to oscillatory or chaotic regions. As a corollary, asymmetric weights cannot lead to stable regions.

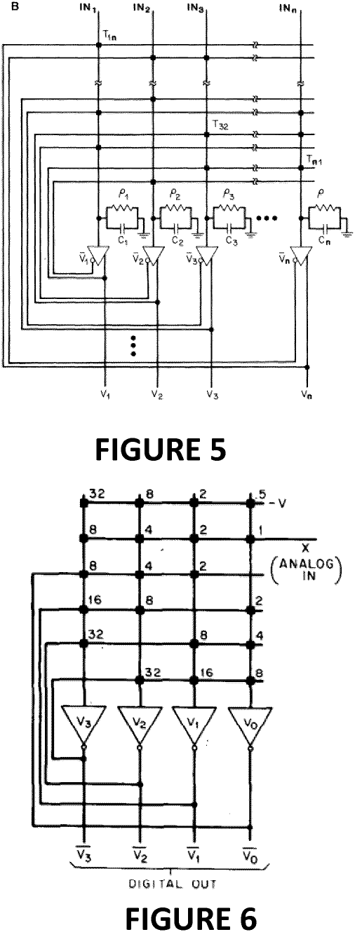

The graded response neural network can be considered as an analog circuit built of amplifiers, resistors, and capacitors. Within the analog circuit, the activation function is represented by the input/output functions of amplifiers, which are sigmoid monotonically increasing functions. The neuron itself is depicted as a subcircuit composed of an amplifier, a reverse amplifier, a capacitor and a resistor (see FIG. 5). The connections are established based on resistances (resistors model the synaptic connections) - such as an amplifier represents an excitatory connection, while the inhibitory one is created through an inverted amplifier. Notably, when the connection matrix with zero diagonal elements is symmetric and the amplifiers are fast in contrast to the RC time property of the input network, a stable state will be found, and no oscillation is expected [25].

In [26], Hopfield and Tank extended the analog neural model and introduced a Hopfield network as a 4-bit analog to digital converter for optimization problems. For example, the analog-to-digital network is used to minimize a preprogrammed energy functions for applications in signal processing and control since the minimization of the energy function can be considered as the cost function of the problem at hand. The organization of the new network is accomplished by modeling the amplifier as a subcircuit of a resistor, capacitor and ground.

The excitatory or inhibitory signals here are depicted as an amplifier or inverted amplifier respectively. The connection between two neurons is built through a resistor with a value of 1/|Tᵢⱼ|. The resistor (representing a synaptic connection) is connected to the amplifier when Tᵢⱼ > 0, and to the inverse amplifier in the reverse case. The total input of the neuron is represented by the summation of the currents form the input resistors, taking into account the external input currents. The outputs from the amplifier, being in the voltage range for the amplifier [0, V_{BB}], is then fed back as amplifier inputs, thereby creating densely connected resistive network. The relative conductance for the feedback connections should follow Tᵢⱼ = -2 (i + j)/V_{BB} with input voltage connected to the amplifier through a resistor with conductance 2 (4 + i)/V_{H}, where V_{H} is the digitized range [0, V_{H}], and with a constant current being provided by a resistor with conductance of (2(i - 1) + (2(2i - 1)/V_{R})) where V_{R} is the reference voltage for the constant input currents.

Following the description, the 4-bit analog/digital converter is modeled using 4 amplifiers (neurons), an array of linear resistors (synapses), which are a symmetric connection matrix with zero diagonal elements. The analog input voltage Vₛ is converted to digital code such that

$${V}_{s} = \sum {2}^{i} {V}_{i}$$

which describes the operation of the Hopfield ADC network, with the voltage level of the output code being equal to the value of the analog input.

The energy function for such a device is defined by:

$$E = \frac{1}{2} {\left(x - {\sum }_{i = 0} {V}_{i} {2}^{i}\right)}^{2}$$

and is used to describe the dynamics of the system. When the minimum value is reached, the network reaches its stable state. At each analog input level, the network creates an energy function surface that consists of local minima states with one global minimum for the particular analog input. The global minimum for each input level represents the correct digital representation for the input signal. When the ADC network arrives at an energy minimum state, it produces an output that best represents the corresponding analog input.

One should point out that with a Hopfield ADC network, the number of synapses grows quadratically with the number of neurons. This necessitates a compact representation of the synapses for the circuit in order to be practical. The network dynamics is highly dependent on the values of the synaptic matrix elements. To reach a stable state, two conditions should be maintained: first the synaptic weight matrix should be symmetrical such that Wᵢⱼ = Wⱼᵢ and secondly, the diagonal synaptic weights that correspond to feedbacks from neurons to their own inputs should be Wᵢᵢ = 0.

In order to form a dynamical system, a precise synaptic connectivity of neurons should be implemented [26, 27]. Moreover, the appropriate connectivity can handle variety of optimization problems, i.e., in signal processing (e.g., analog-to-digital converter), combinatorial problems (e.g., Travelling Salesman Problem), etc. One should note that a design of a system with connections that have certain asymmetry may lead to a constantly oscillating system, although for certain tasks this coordinated oscillation might in fact be a desirable result. The correction connections (the combination of symmetric connections) can achieve desirable phase changes between oscillations. Even in a seemingly asymmetric case [27], the presence of additional hop connections (between several neurons) can establish a symmetric inhibitory connection (this is a well-known case in the visual cortex). Therefore, the type of connections (excitatory or inhibitory), the number of connections and their analog response, as well as the feedback connections present will have a fundamental role in the system capabilities.

In the case of a 4-bit analog-to-binary converter (see FIG. 6), the circuit is described by continuous charge and current, with the action potential being also continuous variable. The network is developed again with amplifiers, wires, resistor and capacitors. Getting an input impedance of a neuron is implemented with resistors and capacitors which are connected in parallel from the amplifier. Nonrectifying synapses are described as a symmetric synapse with a + sign. As shown in FIG. 6 at each of the analog inputs, the network establishes an energy function surface, which has local minima states and one global minimum for each particular analog input. Thus, the global minimum for each input represents the correct digital representation of the input signal.

The firing rates of such neurons are adjusted in such a way that it represents the binary value which is equivalent to the time-average input activity if the energy function described in equation (13) is minimized.

Therefore, the connections will define not only the speed of computations (i.e., the system’s evolution) but also the effect each neuron has on the other neurons. In other words, while the energy is a global state of the system, it is not experienced by individual neurons, but only on the collective work of neurons. Following from this, it can be stated that while individual parts work independently, the system as a whole behaves in a certain energy state. The continuous process is dependent on the particular ample connection matrix.

According to an embodiment, neural network circuits can be built by utilizing such basic elements to represent neurons, more specifically: through amplifiers, wires, resistors and capacitors to implement the equivalent of axons, dendrites, and synapses of a neural network, respectively. The output of a neuron can be represented as the amplifier voltage, while the current form the wires and resistors act as a piece of information flowing through the network. Additionally, the circuit can be represented in the way of connection arrays by using n-flops, to which an amplifier connects. Those systems can then proceed to minimize an energy function, which have stable points corresponding to particular memory/answer. Those flip-flop devices (present in current CMOS hardware) will move the system to converge to a stable state irrespective of the initial state. It should be noted that a flip-flop (JK, T, D) is a single-bit memory cell, used to store digital data and can be synchronous and asynchronous. As such, flip-flops are used in CPU registers, RAM technology, FPGAs, etc. Therefore, the circuit has an initial state and a final state (the answer state) and middle states, through which the network moves through before settling on the final state. Throughout the computation, the data is distributed along the circuit, allowing a single circuit to hold multiple memories.

If we regard a neuron as a qubit, then a weight (synaptic connection) can in turn be represented as a qubit interaction (i.e., interaction between qubits). This means that if we have N number of neurons and N² number of connections, the number of interactions between the N qubits will correspond to N².

The approach of learning patterns in a Hopfield network bears a resemblance to the quantum adiabatic process, where the solution patterns are stored in the energy minima of a Hamiltonian. Hopfield networks have an energy function, where energy decreases over time, so the Hopfield network’s state can evolve over time to a lower energy state. Hopfield networks can be utilized for a variety of optimization problems, as in quantum annealing, and the goal is to select the most suitable connection weights. Network architectures other than the Hopfield network can therefore be considered, especially if they share the property of representing a quantum adiabatic process, where the solution patterns are stored in the energy minima of a Hamiltonian. The Hopfield network is an example of such a network according to which the qubits can be coupled.

### Description of an Embodiment

In this section, there is described the analog computation structure (CMOS Qubit), or circuit-derived qubit, and the connections of a plurality of such CMOS Qubits in the construction of a network (or more precisely, a connectivity topology), such as the Hopfield network, in order to create a quantum analog device (such as an annealer) capable of working at room temperature.

### CMOS Qubit

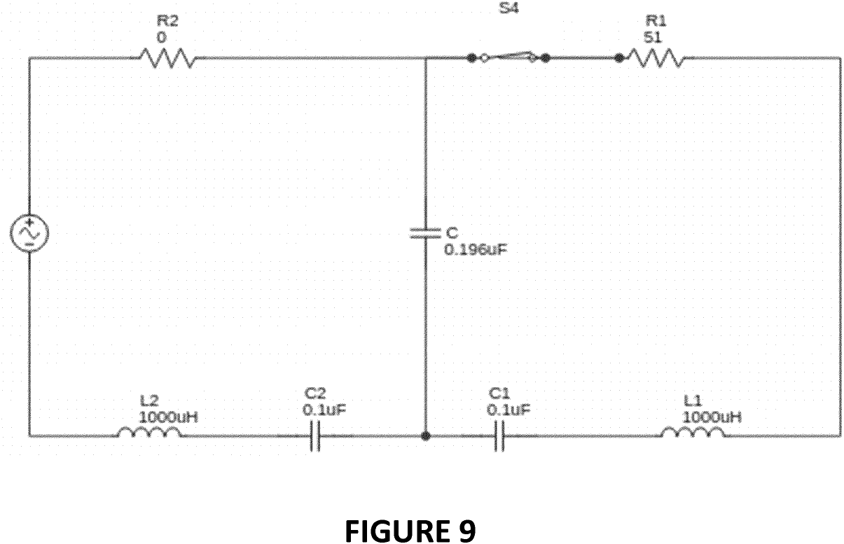

At a macroscopic level, analog computational structures (qubits) are circuits composed by an appropriate number of resistors, inductors, capacitors, a switch and a voltage source or their equivalent, coupled in a particular way to form a qubit (as shown in FIG. 9).

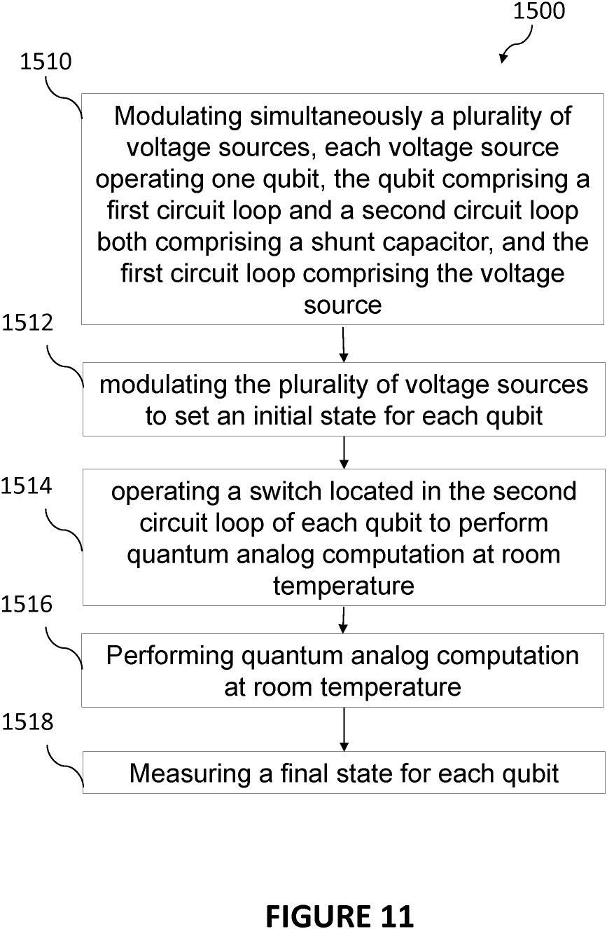

Referring to the circuit of FIG. 9 which illustrates an exemplary embodiment of a qubit made of electronic elements operating at room temperature, and further referring to the method of operating an integrated circuit comprising a plurality of such qubits connected together as shown in FIG. 11, the method 1500 comprises the steps of:
Step 1510: modulating simultaneously a plurality of voltage sources, each voltage source operating one qubit, the qubit comprising a first circuit loop and a second circuit loop both comprising a shunt capacitor, and the first circuit loop comprising the voltage source
Step 1512: modulating the plurality of voltage sources to set an initial state for each qubit;
Step 1514: operating a switch located in the second circuit loop of each qubit to perform quantum analog computation at room temperature;
Step 1516: performing quantum analog computation at room temperature; and
Step 1518: measuring a final state for each qubit.

The integrated circuit, with its connectivity topology, is operable to reach a stable state, and along its evolution toward the stable state, there is, within the integrated circuit, a measurement of the voltage on each qubit to determine the voltage of each qubit associated to a current state (including, at the end, the final state which gives a solution to a given problem) in order to perform computation.

Therefore, the qubits can be initialized and detected (i.e., their parameters can be measured) with extreme accuracy using conventional electronics methods.

As analog computational structures (qubits) are designed with conventional electronic components, they can be miniaturized. A system consisting of a number of connected qubits comprises an integrated circuit implemented on CMOS type hardware using current lithography techniques.

### 1. Connectivity

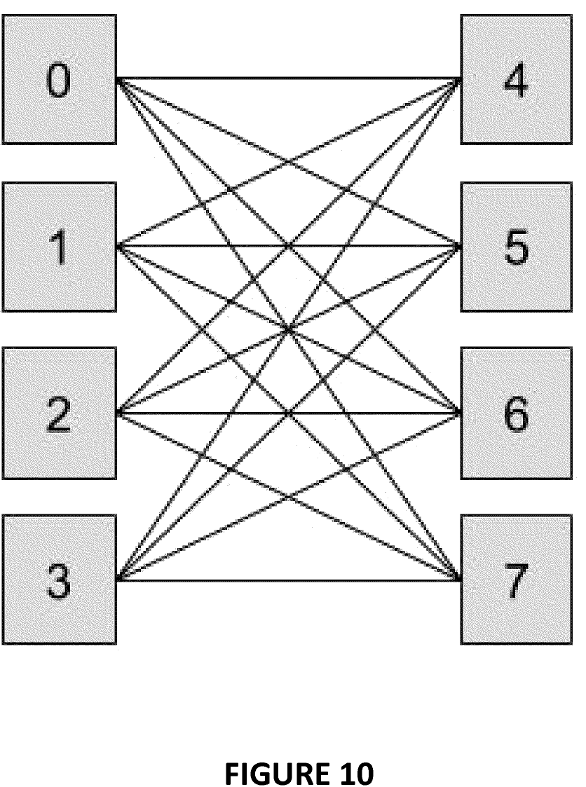

According to an embodiment, the connectivity topology of the CMOS qubits in the system as described herein forms an all-to-all connectivity (example as shown in FIG. 10), such as a Hopfield-type network.

Currently, a variety of possible solutions exist to connect the qubits together - through resistors, capacitors, or with a traditional flip-flop circuit.

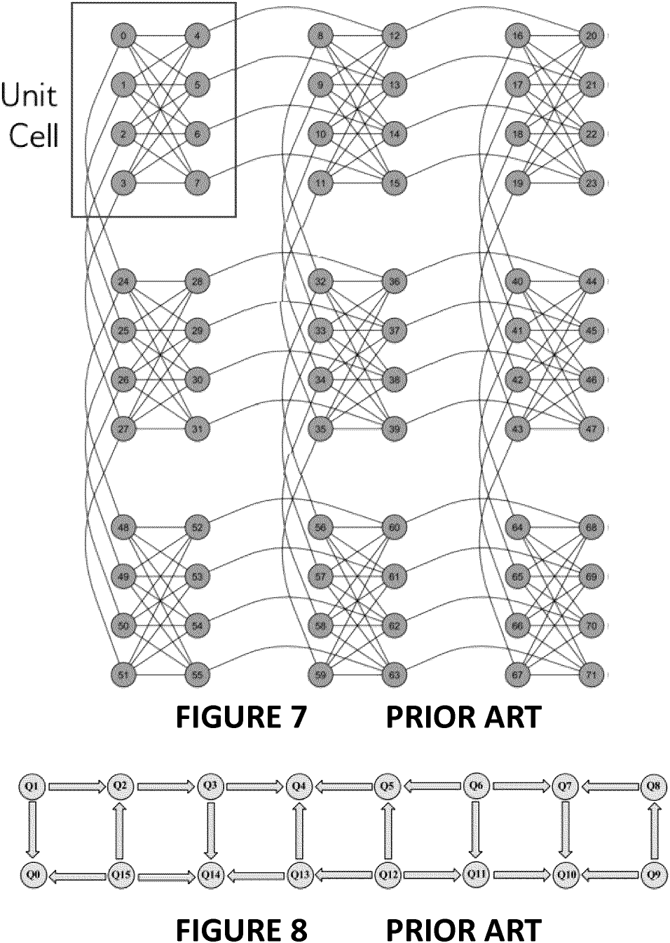

Referring now to existing technologies, to connect over 2000 superconducting flux qubits, in the D-Wave® quantum annealer, they are arranged within unit cells, each having eight qubits, interconnected within the cell, and longitudinally coupled to four other qubits. The cell can be connected as a column or a cross, in a connectivity graph called Chimera (see FIG. 7). A different coupling graph is utilized by IBM (see FIG. 8).

The qubit according to an embodiment described herein is formed by coupled circuits comprised of resistors, capacitors, inductors and a switch or their equivalent to represent an N-level state of an atom. The excitation of the oscillations (moving between quantum states) at a certain frequency presents a path leading to quantum interference. This interference occurs with applying voltage to the coupled circuits. In a Hopfield network (built through amplifiers, resistors and capacitors), qubits are connected together to carry out useful computations by exploiting superposition of states to rapidly search in a space of possible solutions.

The enormous capabilities of the quantum analog computer (which can be used as a quantum annealer) described herein can be derived by the connectivity of qubits in a Hopfield type network, but not limited to this connectivity. A possible approach for connecting multiple qubits is by connecting the qubits with LC-oscillators or a transmission-line-resonator, for instance. Two types of couplings are possible - directly with a capacitor or an inductor, or coupling indirectly. For the direct couplings of qubits with capacitors, one can switch the coupling on and off by tuning the controlling parameters. The capacitance value between two directly coupled qubits Qᵢ and Qⱼ through capacitors Cₘᵢ and Cₘⱼ would be Cₘᵢ Cₘⱼ/(Cₘᵢ + Cₘⱼ). Another suitable approach is by connecting the CMOS qubits in a similar manner to the description of neurons connectivity (such as a Hopfield network), based on simple resistors.

Control of the analog computational structure (qubit) is performed by ADC/DAC with a connected FPGA programming quality to quantum computing at room temperature. We map an optimization algorithm to a hardware implementation of qubits, with the connection between the qubits being a fully connected graph.

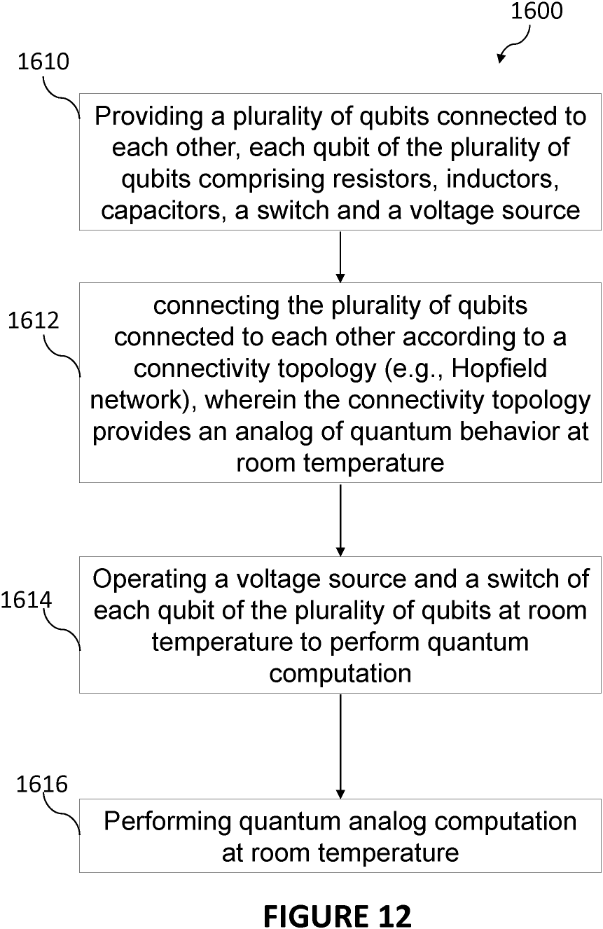

Now referring to FIG. 12, there is shown a method 1600 for performing quantum analog computing using qubits, taking into account the role of their connectivity:
Step 1610: providing a plurality of qubits connected to each other, each qubit of the plurality of qubits comprising resistors, inductors, capacitors, a switch and a voltage source;
Step 1612: connecting the plurality of qubits connected to each other according to a connectivity topology (e.g., Hopfield network), wherein the connectivity topology provides an analog of quantum behavior at room temperature;
Step 1614: operating a voltage source and a switch of each qubit of the plurality of qubits at room temperature to perform quantum computation; and
Step 1616: performing quantum computation at room temperature.

### Experimental Results

As a first step, we will approach the problem by experimental measurements of the computation structure (qubit). Each analog circuit (or qubit) is mathematically equivalent to (or are doppelganger of) an atom in lambda-configuration.

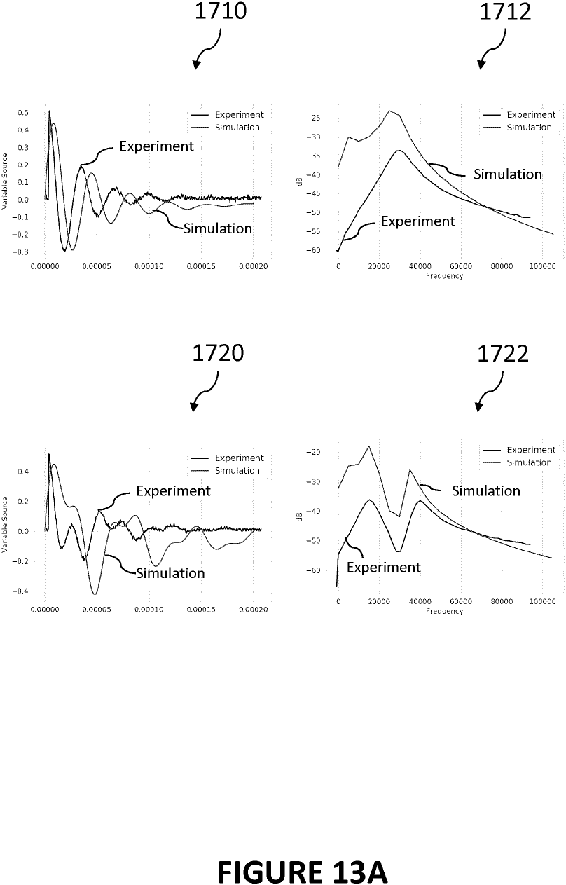

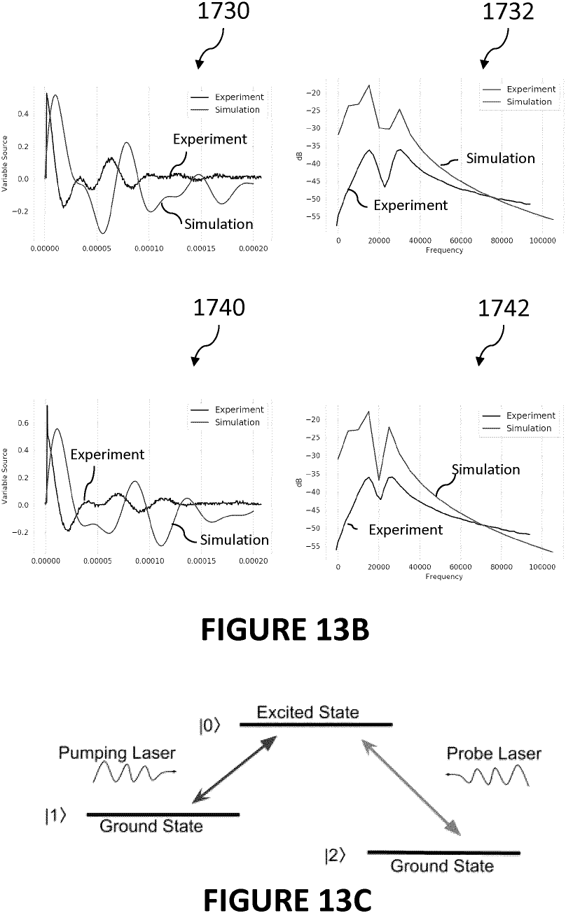

More specifically, in an example showing how the computation structure may be used to be analog to a real-life system, the analog system represents the dynamics of an electron in an atom irradiated by two laser beams (known as pumping and probe), as shown in FIG. 13C, which couple the two ground states to their common excited state (where the states |1〉 and |2〉 are the two ground states while the excited state is represented by |0〉). Within this context, two possible paths are available. This allows exploiting the superposition effect to efficiently explore the space of solution and find the best solution available in that space. The functionality of the analog circuit (which is analog to the behavior of the system of FIG. 13C, and also based on analog electronics) was experimentally verified (by setting-up a system as in FIG. 13C) and compared with the “theoretical” or simulated results (i.e., simulated with CAD design software) obtained during the design phase. The theoretical and experimental results are shown in FIGS. 13A-13B. The left-hand side column depicts the Rabi oscillations (1710, 1720, 1730, 1740) observed during the simulation for different values of the circuit representing the pump laser acting on the system of FIG. 13C of which the circuit is an analog. The right-hand side column represents the corresponding Fourier transforms (1712, 1722, 1732, 1742). From the plots, it is easy to observe how the initial Gaussian shape splits into two peaks as the circuit corresponding to the pump laser influence is increased, a typical signature of certain quantum effects.

Now referring to FIGS. 13A-13B, there is shown a comparison of measured and simulated Rabi oscillations. The left-hand plots depict the Rabi frequency measured experimentally (blue) along with simulation results (red). The right-hand plots represent the corresponding Fourier transform of the Rabi oscillations of the experimental (blue) and computational (red) results. It is evident that the initial Gaussian shape splits into two peaks as the pump laser influence is increased.

To showcase the computational capabilities for the quantum analog device according to an embodiment, two benchmarks were carried out, namely the Traveling Salesperson Problem and the Black-Scholes model.

The first benchmark carried out on the quantum analog device was the Traveling Salesperson Problem. The problem is part of an important category of optimization problems, and it is encountered in various scientific and engineering areas, moreover it is an NP hard problem, necessitating exponential time in order to be solved by brute force method.

FIG. 14A depicts the results for up to 100 cities, obtained by the quantum analog device according to an embodiment. The results pertain to the computational time to reach a first solution. Note, the initial solution can represent a local minimum and thereby one cannot guarantee that the solution is a global one. The plots show that with the addition of more cities, the quantum analog device according to an embodiment always remains in the sub-exponential regime. A comparison with the Gradient Descent method, shown in FIG. 14B, illustrates that the gradient descent continues to grow with each city added. The results for the gradient descent method have been obtained using Intel(R) Core(TM) i7 -7500U running at 2.70 GHz processor.

The second problem involves the ability of the device to tackle partial differential equations (PDEs), in this case is represented as the Black-Scholes equation. The vast majority of PDEs do not have an exact solution and therefore necessitate the use of numerical methods such as the finite difference method (FDM). In the FDM, one discretizes the variable domain and approximates partial derivatives by difference quotients based on Taylor’s theorem. The resultant equation represents a system of linear equations which can be solved via standard linear algebra libraries or recast as an optimization problem.

In the case of the Black-Scholes model, one should note, an exact solution exists only for the pricing of the European options and cannot be used in other cases. At the same time, since the European option model has an exact analytic solution, it can be used for a comparison of results. To this end, the Black-Scholes model has been recast in terms of an optimization problem suitable for running on the quantum analog device. For comparison purposes, the same problem has been computed by using Covariance matrix adaptation evolution strategy (CMA-ES), which is considered a state-of-the-art optimization algorithm, developed by N. Hansen from the French Institute for Research in Computer Science and Automation. Evolution strategies (ES) are stochastic, derivative-free methods for numerical optimization of non-linear or non-convex continuous optimization problems.

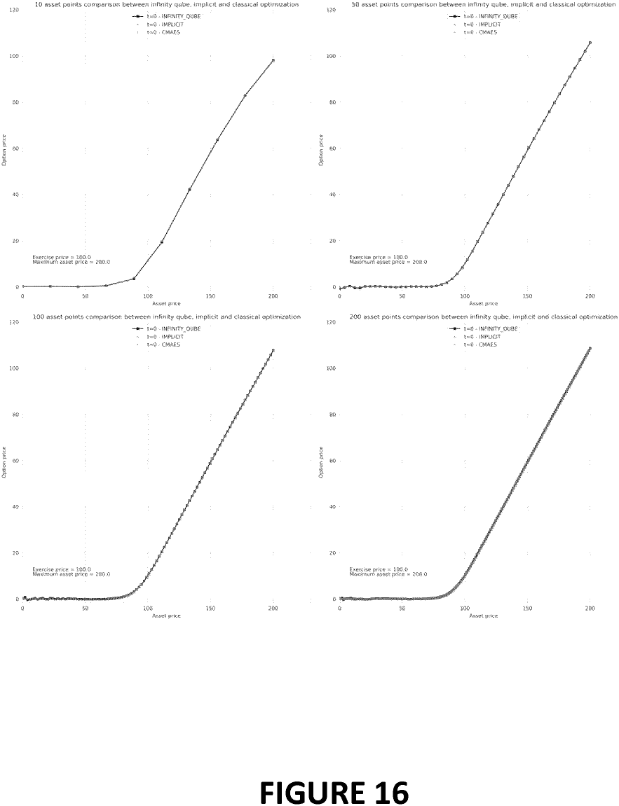

The accuracy of the quantum analog device has been validated for those 4 cases: for 10, 50, 100, and 200 number of asset points per time step (each computation contains 5 time steps) to obtain timing data as the number of variables increase. The accuracy of the quantum analog devices is compared with results obtained with CMAES, as well as a classical implicit method for the European Call, as shown in FIG. 16. In FIG. 16, the accuracy of the quantum analog results is compared to CMAES results and implicit method for the Black Scholes model for 10 (upper left plot), 50(upper right plot), 100 (lower left plot), and 200 (lower right plot) price points. The plots simply show that the point results match the curves.

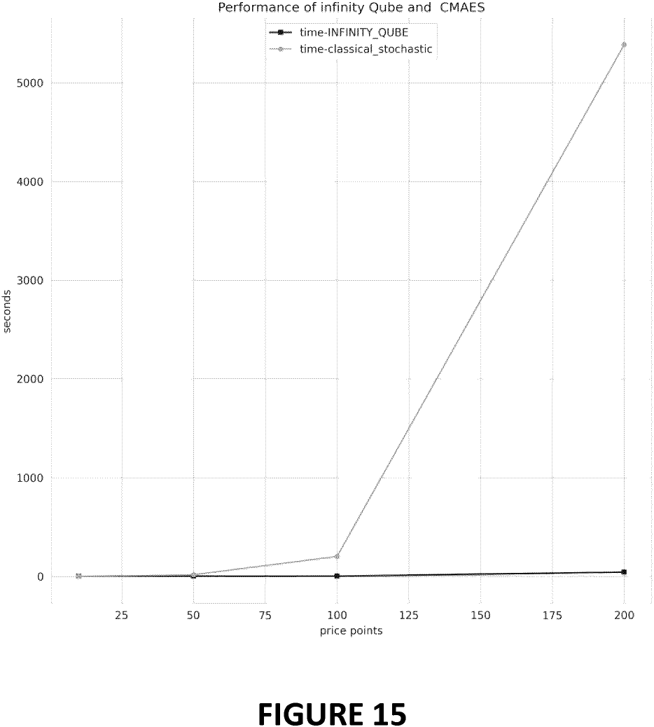

The classical stochastic optimization was carried out on 2 GHz Quad-Core Intel Core i5 device. Table 1 shows the computational performance of the quantum analog device according to an embodiment, against the classical stochastic optimization method (CMAES) implemented on a classical computer processor, which can be also shown in FIG. 15. The results indicate a significant gain of time of computation, as the time of computation does not grow exponentially with the quantum analog device according to an embodiment, as it is the case when using classical methods.

TABLE 1

Black-Scholes timing comparison between the quantum analog device and the classical CMAES method for 10, 50, 100, and 200 asset variables (time is in seconds), as also shown in FIG. 15 .

| Asset price points | Quantum Analog Device | Classical stochastic (CMAES) - Intel |
|---|---|---|
| 10 | 0.027454 | 0.05491 |
| 50 | 0.105662 | 9.987797 |
| 100 | 0.478005 | 176.996106 |
| 200 | 41.470628 | 5862.148043 |

### Scalability

The quantum analog method as described herein does not suffer from scalability issues, since the qubits and connections are built from traditional CMOS type equipment. This ensures the quality of the qubits, making them virtually identical due to the CMOS technology implementation. CMOS scalability and connectivity are ensured since the technology is very well known and understood for decades. Maintenance problems are also well known and relatively cheap to carry out. Most importantly, additional qubits can be added to the system provided the connectivity is precisely calculated, meaning the connectivity can be easily reconfigured. Moreover, as seen in the Hopfield based hardware neural network, we can build application-specific architectures based on classical circuitry (ASIC-like capabilities).

### 7. Conclusions

In summary, an analog computational structure (qubit) can be formed by coupled circuits comprised of resistors, inductors, capacitors and a switch, powered by a voltage source or their equivalent. It can be embodied on a CMOS integrated circuit. A plurality of these CMOS qubits that express the quantum nature of two-level (or N-level) atomic systems can be connected together according to a connectivity topology on an integrated circuit in particular ways. The CMOS Qubits advantageously work at room temperature. It means that typical disadvantages normally associated with cryogenic technology in the context of quantum computing are completely avoided while performing quantum computing.

As mentioned above, the architecture of neural networks can be used as a way to connect a plurality of qubits together according to such an architecture. Advantageously, the architecture of the neural network can be chosen to have a network in which a minimum of energy (stable state) can be reached through the quantum analog computer in which the qubits are connected according to such a network. Without limitation, an example of such a network architecture is the Hopfield network. When the qubits are connected in such a network, they can reach a stable state during operation. This can be used to perform quantum analog computing, such as quantum annealing.

In such a connectivity network, all qubits participate in the computation. Scalability and low maintenance are other benefits of this technology.

While preferred embodiments have been described above and illustrated in the accompanying drawings, it will be evident to those skilled in the art that modifications may be made without departing from this disclosure. Such modifications are considered as possible variants comprised in the scope of the disclosure.

References, incorporated herein by reference, are as follows:
R. Feynman, Simulating physics with computers. International Journal of Theoretical Physics 21, 6&7, 467488, 1982.
Y. Manin. Computable and Uncomputable; Sovetskoye Radio: Moscow, 1980.
John. A. Pople. Nobel lecture: Quantum chemical models. Reviews of Modern Physics 71.5 (1999): 1267.
W. Kohn. Nobel Lecture: Electronic structure of matterwave functions and density functionals. Reviews of Modern Physics 71.5 (1999): 1253.
D. Deutsch. Quantum theory, the ChurchTuring Principle and the universal quantum computer. Proceedings of the Royal Society A, 400(1818), 97, (1985).
Gambetta JM, Chow JM, Ste_en M. Building logical qubits in a superconducting quantum computing system. npj Quantum Information. 2017, Jan 13;3(1):1-7.
Corcoles, Antonio D., et al. “Demonstration of a quantum error detection code using a square lattice of four superconducting qubits.” Nature communications 6.1 (2015): 1-10.
Neill, Charles, et al. “A blueprint for demonstrating quantum supremacy with superconducting qubits.” Science 360.6385 (2018): 195-199.
Krantz, Philip, et al. “A quantum engineer’s guide to superconducting qubits.” Applied Physics Reviews 6.2 (2019): 021318.
Harty, T. P., et al. “High-fidelity preparation, gates, memory, and read out of a trapped-ion quantum bit.” Physical review letters 113.22 (2014): 220501.
Schaefer, V. M., et al. “Fast quantum logic gates with trapped-ion qubits.” Nature 555.7694 (2018): 75-78.
Christopher J. Ballance. Trapped-Ion Qubits. High-Fidelity Quantum Logic in Ca+. Springer, Cham, 2017. 5-14.
Zwanenburg, Floris A., et al. “Silicon quantum electronics.” Reviews of modern physics 85.3 (2013): 961.
Bradley, C. E., et al. “A ten-qubit solid-state spin register with quantum memory up to one minute.” Physical Review X 9.3 (2019): 031045.
Gumann, P., et al. “Inductive measurement of optically hyperpolarized phosphorous donor nuclei in an isotopically enriched silicon-28 crystal.” Physical review letters 113.26 (2014): 267604.
Lester, Brian, et al. “Individual control of an array of neutral atom qubits for quantum computing.” Bulletin of the American Physical Society (2020).
Picken, C. J., et al. “Entanglement of neutral-atom qubits with long ground-Rydberg coherence times.” Quantum Science and Technology 4.1 (2018): 015011.
Farhi E, Goldstone J, Gutmann S, Sipser M. Quantum computation by adiabatic evolution. arXiv preprint quant-ph/0001106. 2000 Jan 28.
Garrido Alzar, C. L., M. A. G. Martinez, and P. Nussenzveig. “Classical analog of electromagnetically induced transparency.” American Journal of Physics 70.1 (2002): 37-41.
Z. Bai, C. Hang, G. Huang. Classical analogs of double electromagnetically induced transparency. Optics Communications, 291, pp.253-2 258,2013.
PW. Shor. Scheme for reducing decoherence in quantum computer memory. Phys Rev A. 1995;52:R2493.
Jordan, Stephen P., Edward Farhi, and Peter W. Shor. “Error-correcting codes for adiabatic quantum computation.” Physical Review A 74.5 (2006): 052322.
N. Chancellor, S. Zohren, P.A. Warburton. Circuit design for multibody interactions in superconducting quantum annealing systems with applications to a scalable architecture. npj Quantum Information, 3(1), pp.1-7.2017.
John, Hopfield. Neural networks and physical systems with emergent collective computational abilities. Proceedings of the national academy of sciences 79.8 (1982): 2554-2558.
John, Hopfield. Neurons with graded response have collective computational properties like those of two-state neurons. Proceedings of the national academy of sciences 81.10 (1984): 3088-3092.
D. Tank, J. J. Hopfield. Simple ‘neural’ optimization networks: An A/D converter, signal decision circuit, and a linear programming circuit. IEEE transactions on circuits and systems 33.5 (1986): 533-541.
J. Hopfield, D. Tank. Computing with neural circuits: A model. Science 233.4764 (1986): 625-633.
Brecht T, Pfaff W, Wang C, Chu Y, Frunzio L, Devoret MH, Schoelkopf RJ. Multilayer microwave integrated quantum circuits for scalable quantum computing. npj Quantum Information. 2016 Feb 23;2(1):1-4.
D-Wave Documentation. Accessed: 14. April 2020. https: ==docs:dwavesys:com=docs=latest=cgs4:html
S.J. Weber,G.O. Samach, D. Hover, S. Gustavsson, D.K. Kim, A. Melville, D. Rosenberg, A.P. Sears, F. Yan, J.L. Yoder, W.D. Oliver. Coherent coupled qubits for quantum annealing. Physical Review Applied, 8(1), p.014004, 2017.
K.L. Pudenz, T. Albash, D.A Lidar. Error-corrected quantum annealing with hundreds of qubits. Nature communications, 5(1), pp. 1-10., 2014.
D. Ferrari, M. Amoretti. Demonstration of envariance and parity learning on the IBM16 qubit processor. arXiv preprint arXiv:1801.02363. 2018.
Jiang, Nian-Quan, et al. “Universal quantum computing with superconducting charge qubits.” arXiv preprint arXiv:1809.01304 (2018).
Mills, Jonathan Wayne, and Charles A. Daffinger. “An analog VLSI array processor for classical and connectionist AI.” [1990] Proceedings of the International Conference on Application Specific Array Processors. IEEE, 1990.
Truitt, Thomas D., and Alan E. Rogers. Basics of analog computers. Vol. 256. JF Rider, 1960.
Barrios, G. Alvarado, et al. “Analog simulator of integro-differential equations with classical memristors.” Scientific reports 9.1 (2019): 1-10.
Ambrogio, Stefano, et al. “Equivalent-accuracy accelerated neural-network training using analogue memory.” Nature 558.7708 (2018): 60-67.
Tait, Alexander N., et al. “Neuromorphic photonic networks using silicon photonic weight banks.” Scientific reports 7.1 (2017): 1-10.
Shen, Yichen, et al. “Deep learning with coherent nanophotonic circuits.” Nature Photonics 11.7 (2017): 441.
Lin, Xing, et al. “All-optical machine learning using diffractive deep neural networks.” Science 361.6406 (2018): 1004-1008.
Tzanakis, Constantinos. “Discovering by analogy: the case of Schrödinger’s equation.” European journal of physics 19.1 (1998): 69.
Eberly, J. H. Seventh Rochester Conference on Coherence and Quantum Optics. ROCHESTER UNIV NY DEPT OF PHYSICS AND ASTRONOMY, 1996.
Scully, M. O. “Zubairy (1997) Quantum optics.” (2002).
Herrmann, F., and G. Bruno Schmid. “Analogy between mechanics and electricity.” European Journal of Physics 6.1 (1985): 16.
Sivardiere, J. “On the analogy between inertial and electromagnetic forces.” European Journal of Physics 4.3 (1983): 162.
Charru, François. “A simple mechanical system mimicking phase transitions in a one-dimensional medium.” European Journal of Physics 18.6 (1997): 417.
Bliokh, Yury P., et al. “Transport and localization in periodic and disordered graphene superlattices.” Physical Review B 79.7 (2009): 075123.
Timp, G., et al. “Nanostructure Physics and Fabrication, edited by MA Reed and WP Kirk.” (1989): 331.
Sols, Fernando, et al. “On the possibility of transistor action based on quantum interference phenomena.” Applied physics letters 54.4 (1989): 350-352.
Wang, Y., and S. Y. Chou. “Quantum wave bandstop filters.” Applied physics letters 65.16 (1994): 2072-2074.
Weisshaar, A., et al. “Analysis of discontinuities in quantum waveguide structures.” Applied physics letters 55.20 (1989): 2114-2116.
Weisshaar, Andreas, et al. “Analysis and modeling of quantum waveguide structures and devices.” Journal of applied physics 70.1 (1991): 355-366.
Gaylord, Thomas K., G. N. Henderson, and Elias N. Glytsis. “Application of electromagnetics formalism to quantum-mechanical electron-wave propagation in semiconductors.” JOSA B 10.2 (1993): 333-339.
Gaylord, T. K., and K. F. Brennan. “Electron wave optics in semiconductors.” Journal of applied physics 65.2 (1989): 814-820.
Gaylord, T. K., E. N. Glytsis, and K. F. Brennan. “Electron-wave quarter-wavelength quantum well impedance transformers between differing energy-gap semiconductors.” Journal of applied physics 67.5 (1990): 2623-2630.
Carati, A., and L. Galgani. “Theory of dynamical systems and the relations between classical and quantum mechanics.” Foundations of Physics 31.1 (2001): 69-87.

1. An integrated circuit for quantum analog computing, the integrated circuit comprising:
a plurality of qubits connected to each other, each qubit of the plurality of qubits comprising resistors, inductors, capacitors and a switch, wherein the qubits are connected to each other according to a connectivity topology that provides an analog of quantum behavior at room temperature.

2. The integrated circuit of claim 2, the connectivity topology is a Hopfield network.

3. The integrated circuit of claim 3, wherein each qubit in the Hopfield network is connected to all other qubits of the Hopfield network.

4. The integrated circuit of any one of claims 1 to 3, wherein the qubits are connected to each other using at least one of: an inductor and a capacitor.

5. The integrated circuit of any one of claims 1 to 4, wherein each qubit comprises a metal oxide semiconductor (CMOS).

6. The integrated circuit of any one of claims 1 to 5, wherein the qubits are operating at a room temperature.

7. The integrated circuit of claim 6, wherein the qubits are operating at a temperature of between 0 and 30 degrees Celsius.

8. The integrated circuit of any one of claims 1 to 7, wherein each qubit of the plurality of qubits comprises:
a first resistor, a voltage source, a first inductor, a first capacitor, and a shunt capacitor connected in a first series circuit, the shunt capacitor having a first node on one side and a second node on another side; and
the switch, a second resistor, a second inductor, and a second capacitor connected in series and forming a second series, the second series being connected in parallel to the shunt capacitor at the first node and the second node.

9. The integrated circuit of claim 8, wherein the voltage source is controlled to set each qubit with a particular initial state.

10. The integrated circuit of claim 9, wherein the integrated circuit is operable to reach a stable state, the integrated circuit measuring a voltage on each qubit to determine the voltage of each qubit associated to a current state in order to perform computation.

11. A method comprising:
providing and connecting a plurality of qubits connected to each other according to a connectivity topology which is an all-to-all topology, each qubit of the plurality of qubits comprising resistors, inductors, capacitors and a switch to be equivalent to an atomic qubit;
setting an initial voltage of each qubit of the plurality of qubits; and operating the plurality of qubits at the room temperature to reach a final state representative of a solution to a given problem and measuring an associated voltage of each one of the plurality of qubits to perform quantum analog computation to determine the solution.

12. The method of claim 11, further comprising operating amplifiers used to connect the qubits by the connectivity topology.

13. The method of claim 12, wherein connecting the plurality of qubits according to the connectivity topology comprises connecting the plurality of qubits according to a Hopfield network built with resistors and capacitors.

14. The method of claim 13, wherein each qubit in the Hopfield network is connected to all other qubits of the Hopfield network.

15. The method of any one of claims 11 to 14, wherein providing and connecting a plurality of qubits comprises connecting each qubit to all other qubits of the plurality of qubits using at least one of: an inductor and a capacitor.

16. The method of any one of claims 11 to 15, wherein each qubit comprises a metal oxide semiconductor (CMOS).

17. The method of any one of claims 11 to 16, wherein the qubits are operated at a temperature between 0 and 30 degrees Celsius.

18. The method of any one of claims 11 to 17, wherein each qubit is connected to a plurality of other qubits and all qubits participate in calculation, such that no qubit is used for error correction.
